(19) United States
(12) Patent Application Publication
(10) Pub. No.: US 2004/0266170 A1
(43) Pub. Date: Dec. 30, 2004

(54) Method of forming contacts in semiconductor device

(76) Inventor: Cheol-Ju Yun, Gyeonggi-do (KR)

Correspondence Address: MARGER JOHNSON & McCOLLOM, P.C., 1030 S.W. Morrison Street, Portland, OR, 97205, US

(21) Appl. No.: 10/869,787

(22) Filed: Jun. 15, 2004

(30) Foreign Application Priority Data
Jun. 27, 2003 (KR) 2003-42644

(51) Int. Cl. H01L 21/4763

(52) U.S. Cl. 438/622; 438/629; 438/626; 438/627

(57) ABSTRACT

Embodiments prevent or substantially reduce a short based on a misalignment caused between contacts formed vertically to a bit line in a semiconductor device. Some embodiments include forming a contact between line patterns on a semiconductor substrate on which the line patterns are surrounded with an insulation layer and each line pattern is composed of a bit line conductive layer and a capping layer. The method includes forming a masking layer on the insulation layer and the line patterns, the masking layer being for masking a portion where the contact is not formed among upper parts of the insulation layer and the line pattern; forming a contact hole between the line patterns by etching the insulation layer through use of the masking layer as an etch mask; forming a spacer in a sidewall of the contact hole; and filling up the contact hole with conductive material to form the contact.

### CROSS REFERENCE TO RELATED APPLICATIONS

This application claims priority from Korean Patent Application No. 2003-0042644, filed on 27 Jun. 2003, the contents of which are hereby incorporated by reference for all purposes.

### BACKGROUND OF THE INVENTION

1. Field of the Invention

This disclosure relates to a manufacturing of semiconductor device, and more particularly, to a method of forming a contact for electrically connecting between a conductive layer and a conductive layer which are formed on different layers.

2. Description of the Related Art

As the requirements for low electricity consumption and high performance of semiconductor devices gradually increases, the semiconductor memory devices tend to obtain a high integration and high-speed operation. However, in order to integrate more semiconductor devices in a semiconductor chip having a limited size, a design rule should be continuously reduced to form numerous contacts in a limited area. Further, in order to improve a characteristic of semiconductor device, an SAC (Self-Aligned Contact) etching technique is being widely used.

In forming the SAC, there also are many problems, especially, that it is serious in an insulated problem between contacts formed between a bit line and a bit line, and between self-aligned contacts, in case a semiconductor device has a design rule of 0.14 μm or below. In this insulated problem, a misalignment is caused by a limited technology of photolithography in forming the contact between the bit lines. The misalignment may result in a short between a bit line and a contact and between the self-aligned contacts, and in the ultimate failure of the semiconductor device due to a malfunction. An ultimate cause for this fail occurrence is that various kinds of nitride layers used on a conductor are lowered together and thus masks of these nitride layers do not serve as an effective mask in a subsequent contact formation.

To solve this problem, the conventional art uses a masking layer that is specifically formed on an upper part of line pattern formed of a bit line and a nitride layer, to be used as a mask so as to increase a precision in a photolithography process. However, the masking layer is formed on the line pattern to enable to prevent a misalignment between the bit line and the contact, but, in a vertical direction of the line pattern, only a photoresist pattern used in a general photolithography process is formed on an insulation layer to be used as a mask, thus there is a problem that a misalignment between contacts formed in a direction vertical to the line pattern can't be prevented. This is caused when a thickness of photoresist becomes low to obtain finer patterning in cases where the semiconductor device has a design rule of 100 μm or below, an over etch is needed to prevent a contact hole from being not opened, and herewith, the lowered photoresist does not have a sufficient function as the mask.

A contact forming method of the conventional art is described as follows, to more thoroughly understand the causes of the problems, referring to FIGS. 1 through 13.

FIG. 1 is a layout diagram showing an etch mask pattern for a formation of contact according to the conventional art. FIGS. 2 to 5 are perspective diagrams illustrating a process sequence in a contact forming method according to the conventional art, and some drawings are illustrated as a solid type for more exactly understanding a sectional face of line I-I′ shown in FIG. 1. Furthermore, FIG. 13 is a sectional diagram along the line II-II′ shown in FIG. 1, illustrating a contact formed according to the conventional art.

In FIG. 1, reference number “100” indicates an active mask window for defining an active region and an inactive region, and reference number “110” designates a gate mask window for forming a gate pattern, and reference number “120” represents a bit line mask window for forming a bit line. Reference number “130” indicates a photoresist pattern as an etch mask, for forming a self-aligned contact.

FIGS. 2 to 5 illustrate a method of forming a contact according to the conventional art and are described in detail as follows.

Referring first to FIG. 2, a second interlayer insulation layer 204 is formed on an entire face of semiconductor substrate on which a contact pad 202 surrounded with the first interlayer insulation layer 200 is formed, and then, on the second interlayer insulation layer 204, a bit line conductive layer 206 and a capping layer 208 are sequentially formed. The capping layer 208 is formed of a nitride layer having an etch selection rate for the second interlayer insulation layer 204, and the bit line conductive layer 206 is formed of tungsten as conductive material. Next, a photolithography and etching process is performed on the bit line conductive layer 206 and the capping layer 208, to form a plurality of line patterns 209 adjacent to each other in a line by a stripe type, the plurality of line patterns 209 being composed of the bit line conductive layer 206 and the capping layer 208. Then, a third interlayer insulation layer 210 is formed on an entire face of semiconductor substrate containing the line patterns 209.

With reference to FIG. 3, the third interlayer insulation layer 210 is flattened through a chemical mechanical polishing (CMP) or an etch back method etc. by using the capping layer 208 as a flattening stopper, so that upper surfaces of the third interlayer insulation layer 210 and the capping layer 208 exist on the same line.

Referring to FIG. 4, a photoresist pattern 214 masked vertically to the line pattern is formed on the third interlayer insulation layer 210 and the capping layer 208, exposing a portion where a self-aligned contact will be formed, and a portion of line pattern, and masking a portion of the third interlayer insulation layer and the capping layer. Subsequently, the third and second interlayer insulation layers 210, 204 are sequentially etched by using the photoresist pattern 214 and the capping layer 208 as an etch mask, to thus form a contact hole between the line patterns 209 formed by a stripe type in a line. Then, the remaining photoresist pattern 214 is removed by an ashing process.

Referring to FIG. 5, a spacer 216 is formed on a sidewall of the contact hole, and then, the contact hole 216 is filled with conductive material.

According to the above-described conventional art, an upper part of the line pattern is masked only with the capping layer, thus a misalignment is caused in an etching process to form the contact hole and an electrical short occurs between the bit line and the self-aligned contact. Further, a vertical direction to the line pattern is masked only with a thin photoresist pattern, thus an electrical short occurs between a contact and a contact formed vertically to the line pattern.

In order to solve these problems, a specific masking layer is formed on the line pattern, to be used as an etch mask, thereby preventing the short between the bit line and the contact. FIGS. 6 through 13 illustrate a process sequence in a contact forming method according to another example of the conventional art.

Referring first to FIG. 6, the second interlayer insulation layer 204 is formed on an entire face of the semiconductor substrate on which the contact pad 202 surrounded with the first interlayer insulation layer 200 is formed, and then, on the second interlayer insulation layer 204, a bit line conductive layer 206 and a capping layer 208 are sequentially formed. The capping layer 208 is formed of a nitride layer having an etch selection rate for the second interlayer insulation layer 204, and the bit line conductive layer 206 is formed with tungsten as conductive material. Next, a photolithography and etching process is performed on the bit line conductive layer 206 and the capping layer 208, to form the plurality of stripe-type line patterns 209 adjacent to each other, the plurality of line patterns 209 being composed of the bit line conductive layer and the capping layer. Then, the third interlayer insulation layer 210 is formed on an entire face of semiconductor substrate containing the line patterns 209.

With reference to FIG. 7, the third interlayer insulation layer 210 is flattened through a chemical mechanical polishing (CMP) or an etch back method etc. by using the capping layer 208 as a flattening stop layer, so that upper surfaces of the third interlayer insulation layer 210 and the capping layer 208 exist on the same line. Subsequently, only the capping layer 208 is selectively etched by a predetermined amount, to form recesses in upper parts of the line patterns.

In FIG. 8, a masking layer 212 is formed on an entire face of the semiconductor substrate containing the recesses, then, the masking layer 212 is flattened through the CMP or the etch back method etc. so that the upper surfaces of the third interlayer insulation layer 210 and the masking layer 212 exist on the same line.

In FIG. 9, the photoresist pattern 214 masked vertically to the line pattern is formed on the third interlayer insulation layer 210 and the masking layer 212, exposing a portion where a self-aligned contact will be formed, and a portion of the line pattern, and also masking a portion of the third interlayer insulation layer and the capping layer.

In FIG. 10, the third and second interlayer insulation layers 210, 204 are sequentially etched by using the photoresist pattern 214 and the masking layer 212 as an etch mask, to thus form a contact hole between the stripe-type line patterns 209 formed in a line. Then, the remaining photoresist pattern 214 is removed by an ashing process.

In FIG. 11, the spacer 216 is formed on a sidewall of the contact hole, and next, a contact plug 218 obtained by filling the contact hole with conductive material.

In FIG. 12, the remaining masking layer 212 is removed through a flattening process such as CMP, etc. by using a silicon nitride layer formed on the line pattern as a flattening stop layer, to thus form a storage node contact.

FIG. 13 is a cross-sectional diagram along the line II-II′ shown in FIG. 1, illustrating the contact formed according to the conventional art.

With reference to FIG. 13, a gate oxide layer 220, a gate conductive layer 222, and a gate capping layer 224 are sequentially accumulated on the semiconductor substrate, and on an active region, a storage contact pad 226 and a bit line contact pad 228 are formed. Then, the second interlayer insulation layer 204 and the third interlayer insulation layer 210 are accumulated, and in line with that, a storage pad contact 218 piercing through the second interlayer insulation layer 204 and the third interlayer insulation layer 210 is formed. That is, according to the conventional art, if a misalignment occurs in forming the storage node contact, an electrical short between the storage node contacts is caused as shown in FIG. 13.

According to the conventional art, the masking layer is formed only on the line pattern to be used as an etch mask, thus preventing a misalignment between a bit line and self-aligned contacts. However, a thin photoresist is used as an etch mask in a direction vertical to the bit line that causes misalignment between the self-aligned contacts in a vertical direction to the bit line. Thus, shorts may still occur. Furthermore, as design rules of semiconductor devices become finer than 0.14 μm, such a misalignment occurs more frequently, leading to increased failures for the semiconductor device.

Embodiments of the invention address these and other disadvantages of the conventional art.

### SUMMARY OF THE INVENTION

Some embodiments of the invention provide a method of forming a contact in a semiconductor device, in which a misalignment between contacts formed in a vertical direction to a bit line can be prevented. In this method, a short between the contacts formed in a vertical direction to a bit line can be prevented. Furthermore, according to some embodiments of the invention a masking layer may be formed that masks an upper part of bit line and which is also masked vertically to the bit line. According to other embodiments of the invention, a masking layer can be stepped with the masking layer for masking the upper part of bit line, being masked vertically to the bit line.

### BRIEF DESCRIPTION OF THE DRAWINGS

The above and other features of examplary embodiments of the invention will become readily apparent from the description that follows, with reference to the attached drawings.

FIG. 1 is a layout diagram of an etch mask pattern for forming a contact according to the conventional art.

FIGS. 2 through 5 are perspective diagrams illustrating a process sequence taken along line I-I′ of FIG. 1.

FIGS. 6 through 12 are perspective diagrams illustrating a process sequence taken along line I-I′ of FIG. 1 according to another conventional example of forming a contact.

FIG. 13 is a cross-sectional diagram taken along line II-II′ of FIG. 1.

FIG. 14 is a layout diagram of an etch mask pattern for forming a contact according to an embodiment of the invention.

FIGS. 15 through 23 are perspective diagrams illustrating a process sequence taken along line I-I′ of FIG. 14.

FIG. 24 is a cross-sectional diagram taken along line II-II′ of FIG. 14, illustrating a contact formed according to an embodiment of the invention.

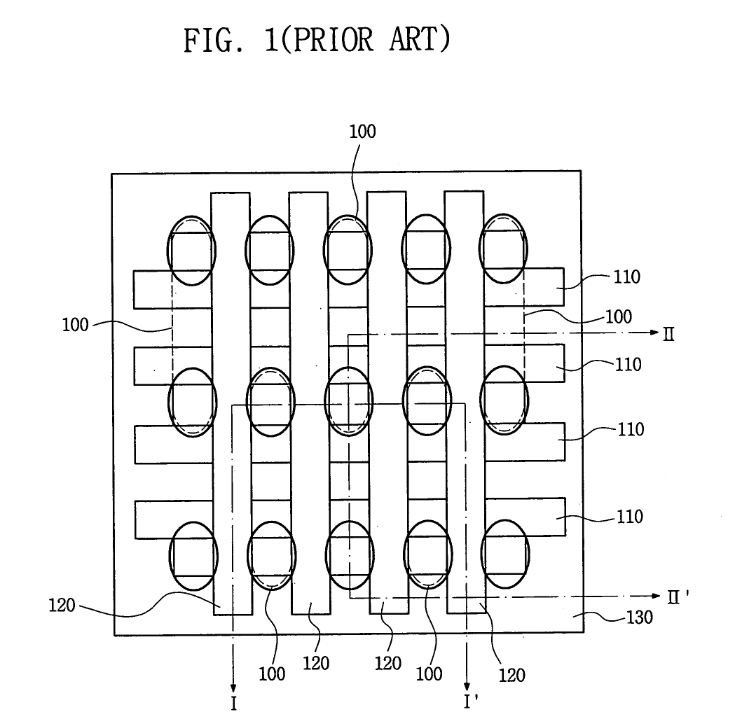

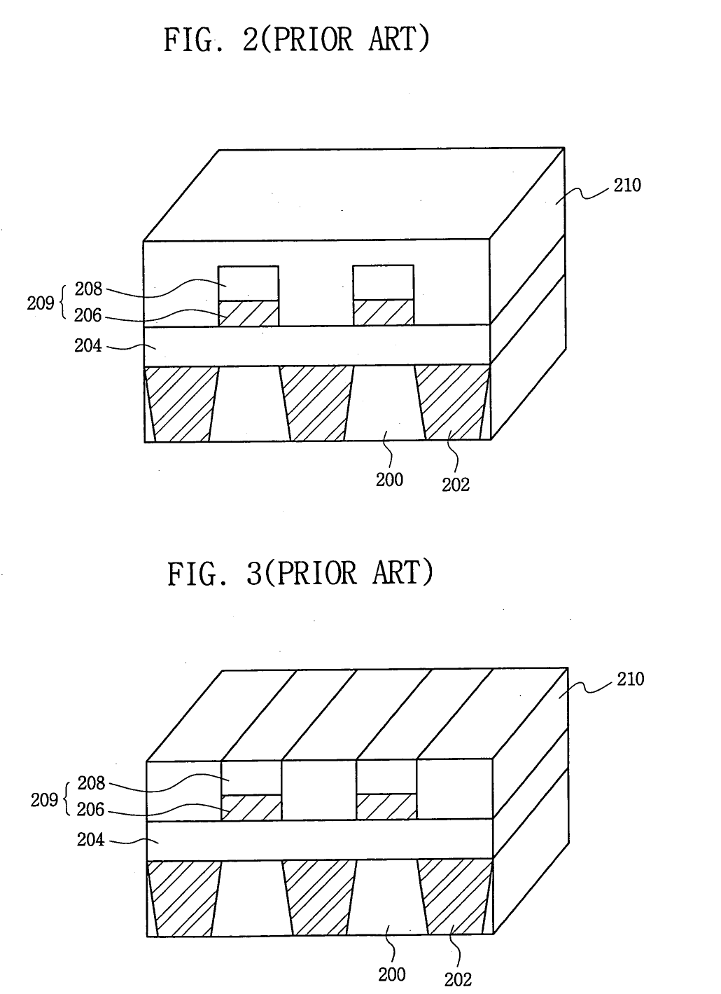

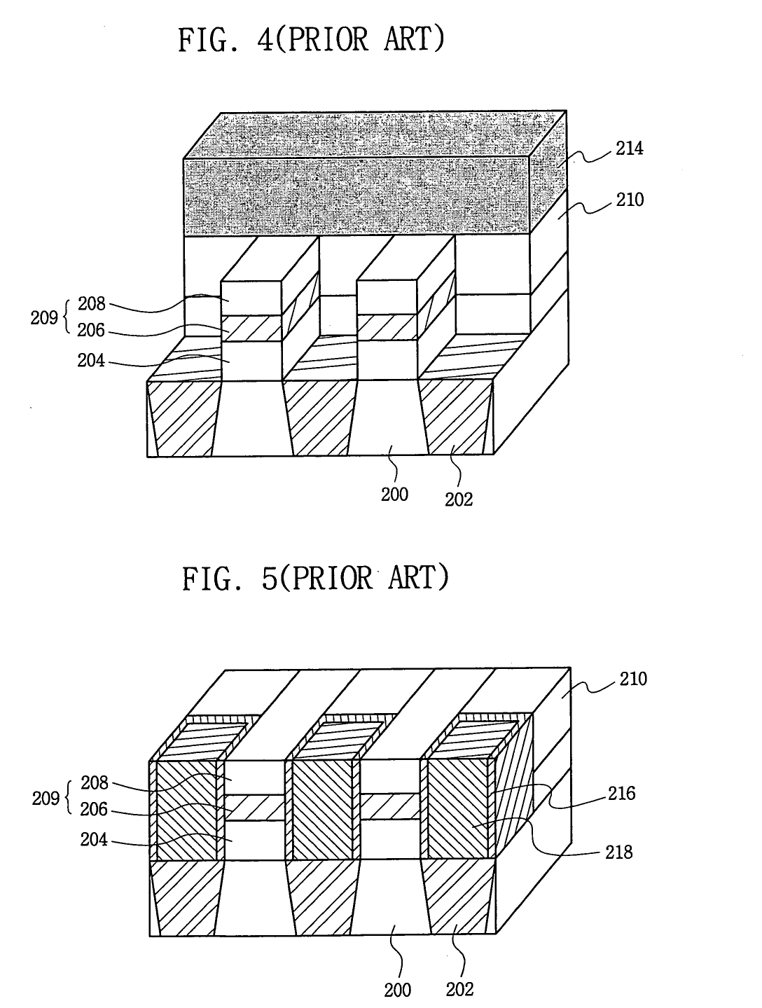

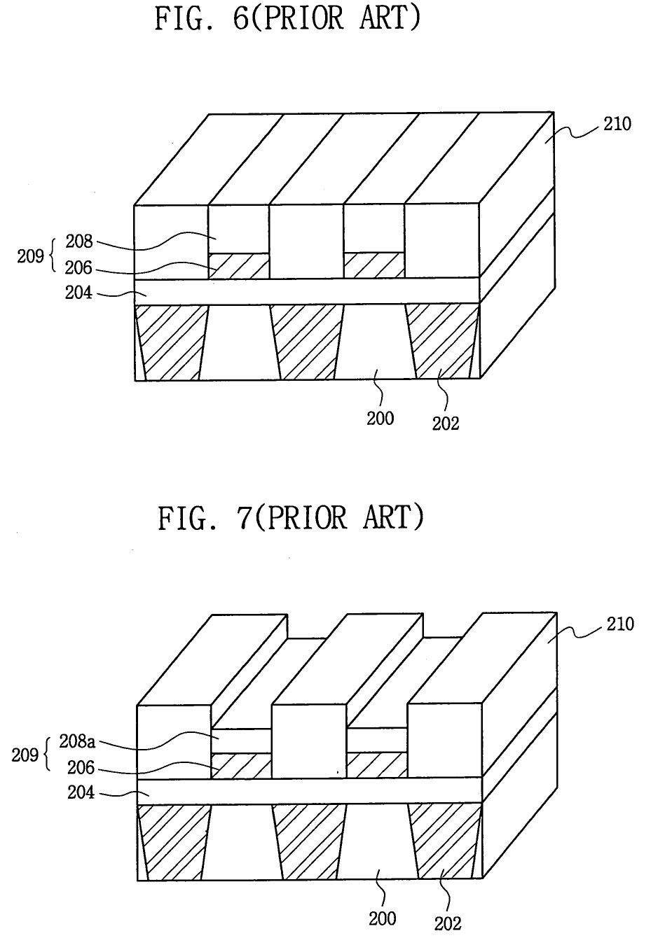

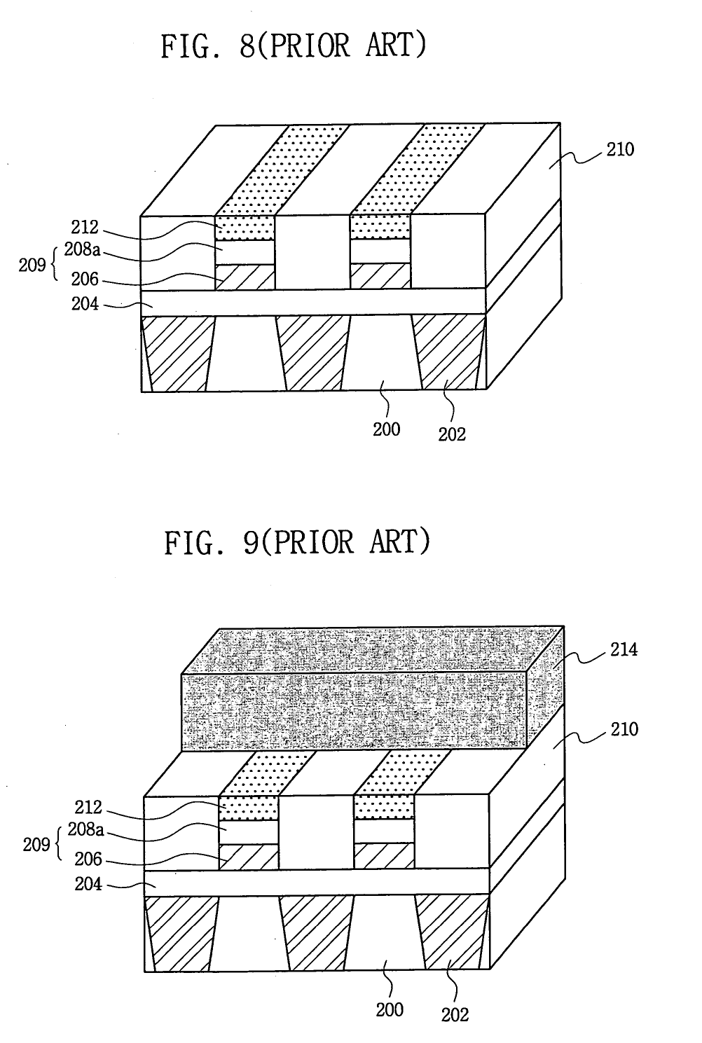

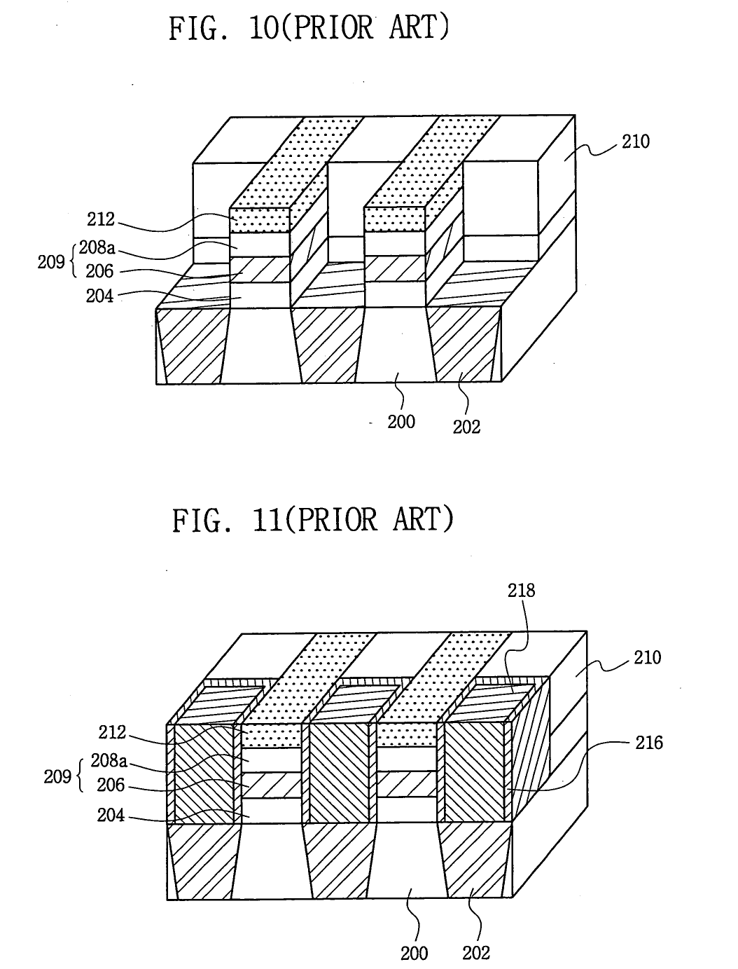

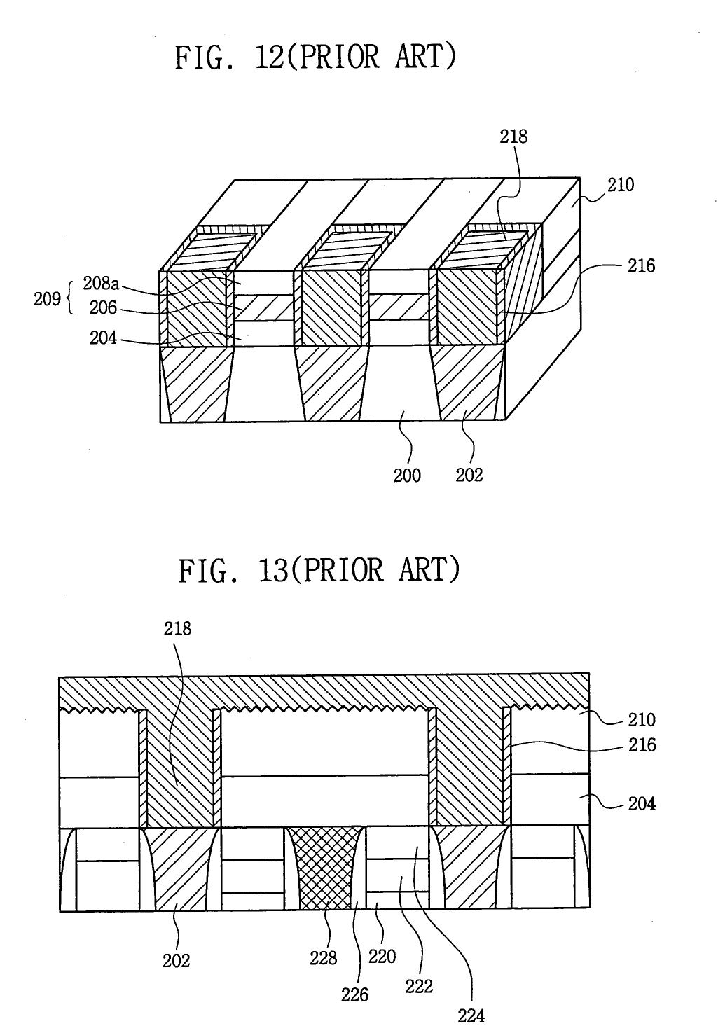

### DETAILED DESCRIPTION OF THE INVENTION

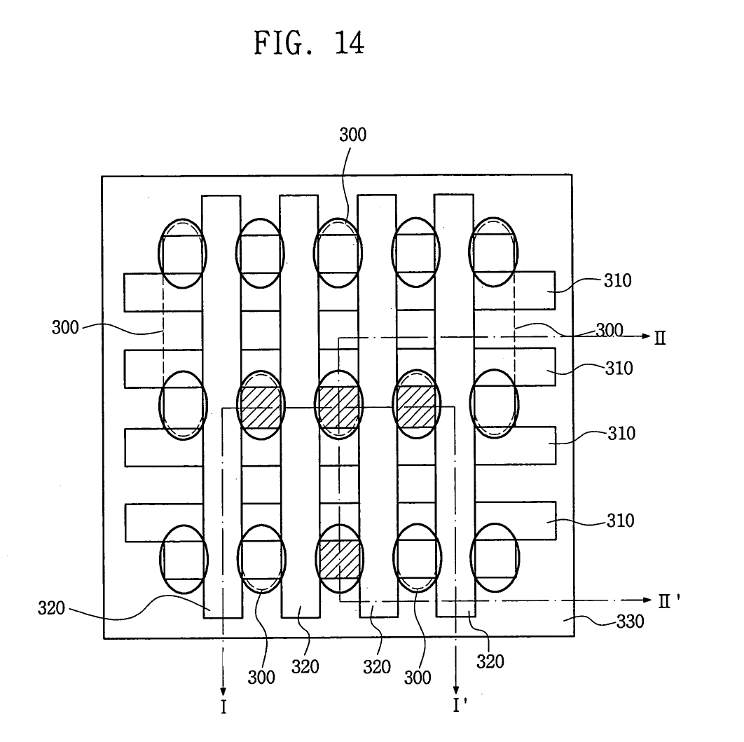

Exemplary embodiments of the invention are more fully described below with reference to FIGS. 14 through 24. The invention may be embodied in many different forms and should not be construed as being limited to the exemplary embodiments set forth herein. Rather, these exemplary embodiments are provided so that this disclosure is thorough and complete, and to convey the concept of the invention to those skilled in the art.

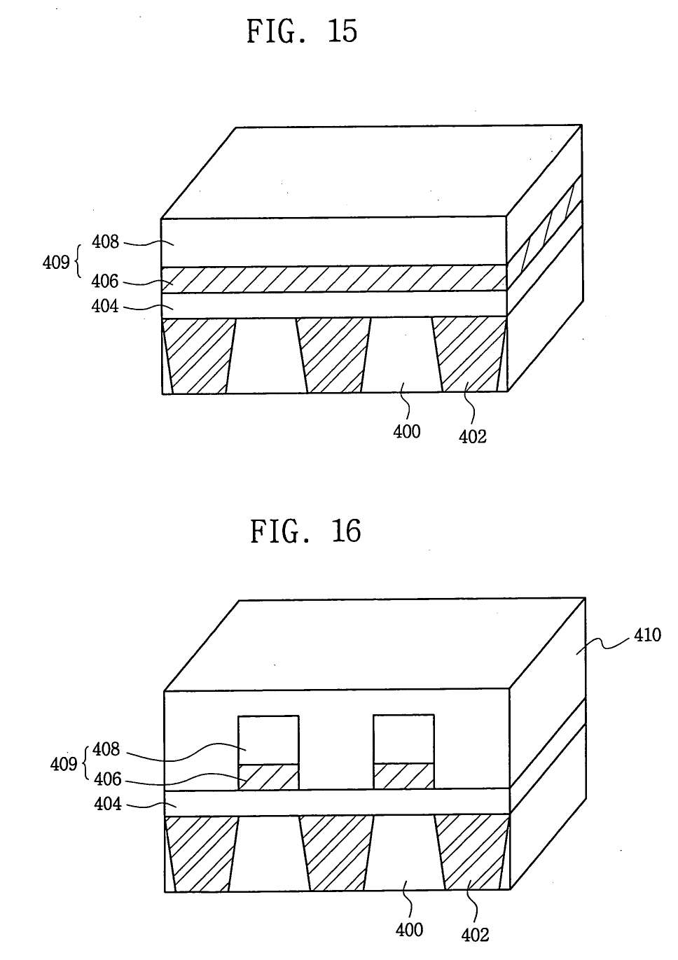

FIG. 14 is a layout of an etch mask pattern for forming a contact according to an embodiment of the invention. FIGS. 15 through 23 are perspective diagrams illustrating a process sequence taken along line I-I′ of FIG. 14 in a contact forming method according to an embodiment of the invention. FIG. 24 is a cross-sectional diagram taken along line II-II′ of FIG. 14, illustrating a contact formed according to an embodiment of the invention.

In FIG. 14, an active mask window 300 defines an active region and an inactive region, and a gate mask window 310 is for forming a gate pattern. A bit line mask window 320 is used for forming a bit line, and a photoresist pattern 330 is used as an etch mask for forming a self-aligned contact.

FIGS. 15 through 23 are perspective diagrams illustrating sequential processes of forming a contact in a semiconductor device according to an embodiment of the invention.

Referring first to FIG. 15, a second interlayer insulation layer 404 is formed on a face of semiconductor substrate on which a contact pad 402 surrounded with a first interlayer insulation layer 400 is formed. Subsequently, on the second interlayer insulation layer 404, a bit line conductive layer 406 and a capping layer 408 are sequentially formed.

The second interlayer insulation layer 404 can be formed through a CVD (Chemical Vapor Deposition), an LPCVD (Low Pressure Chemical Vapor Deposition), or a PECVD (Plasma Enhanced Chemical Vapor Deposition). Furthermore, the second interlayer insulation layer 404 can be formed of a USG (Undoped Silicate Glass), a BPSG (Boron Phosphorus Silicate Glass), a PSG (Phosphor Silicate Glass), or PE-TEOS (Plasma Enhanced Tetra Ethyl Otho Silicate).

Though was not shown in the drawing, a barrier layer may also be formed on the second interlayer insulation layer 404 before forming the bit line conductive layer 406. For example, it can be formed of a dual layer composed of, e.g., a Ti layer/TiN layer. It goes without saying that the barrier layer is not limited to the dual layer composed of a Ti layer/TiN layer.

The bit line conductive layer 406 can be formed through a general method, e.g., the CVD, the LPCVD, or the PECVD process. The bit line conductive layer 406 can be formed of a single layer composed of a silicide layer containing a polysilicon layer, e.g., a tungsten silicide layer, and can be also formed by a polycide structure. In addition, if a bit line is formed by the polycide structure, the bit line conductive layer 406 can be formed of multilayer. For instance, if the bit line conductive layer 406 is formed of a dual layer, a polysilicon layer and a silicide layer are formed sequentially, and then, the capping layer 408 and a masking layer 412 can be formed in sequence. The silicide layer may be a silicide layer of refractory metal such as Ti, Ta, W, Ni, Cr, Ir, or Ru. If the bit line conductive layer 406 is formed of a single layer, it can be formed with a thickness of 1000 Å through 2000 Å. Furthermore, if the bit line conductive layer 406 is formed of dual layer which is composed of the sequentially accumulated polysilicon layer and silicide layer, the polysilicon layer can be formed with a thickness of 500 Å through 1000 Å, and the silicide layer can be formed with a thickness of 1000 Å through 2000 Å.

The capping layer 408 can be formed of a silicon nitride layer which has an etch selection rate for an interlayer insulation layer made of oxide series, through the CVD, the LPCVD, the PECVD, an SACVD (Semi-Atmospheric Chemical Vapor Deposition), a sputtering method, or an atomic layer deposition. If the capping layer 408 is formed of a nitride layer, it can be formed of a general silicon nitride layer having a refractive index of about 2, or it may be more desirable to use a nitride layer having a refractive index of 2.2 through 2.5 in which silicon is more abundant. The nitride layer with greater refractive index reduces stress by about ½ through ⅓ as compared with the general silicon nitride layer, thus, even though the capping layer is formed thickly, stress fractures may be prevented since an etch resistance force against an etchant used for etching an insulation layer of the oxide series becomes large. A thickness of the capping layer 408 is determined by considering a function of the capping layer (as an etch mask, etc.) in a subsequent step, and it is desirable to form the capping layer to a thickness of 500 Å through 2000 Å.

Referring to FIG. 16, a photolithography and etching process are performed on the bit line conductive layer 406 and the capping layer 408, to form a plurality of strip-type line patterns 409 adjacent to each other, the line pattern 409 being composed of the bit line conductive layer 406 and the capping layer 408. Next, a third interlayer layer 410 is formed on a face of the semiconductor substrate containing the line patterns 409. The third interlayer insulation layer 410 can be formed through the same method as the method used to form the second interlayer insulation layer 404, and can be formed of the same material layer as the material layer used to form the second interlayer insulation layer 404.

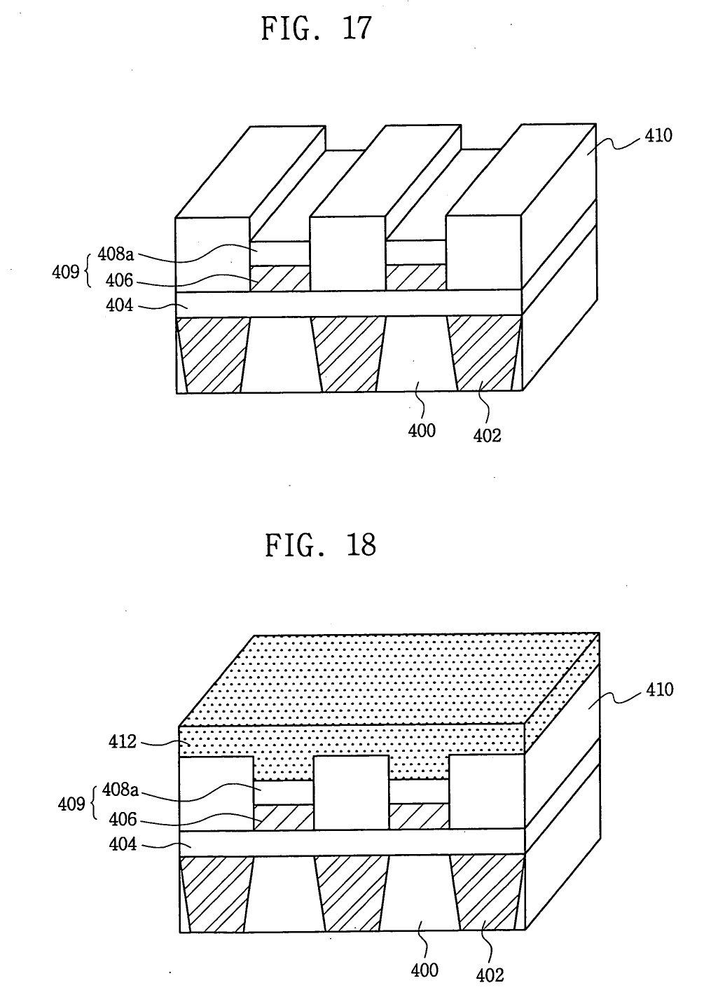

With reference to FIG. 17, the third interlayer insulation layer 410 is flattened by using the capping layer 408 as a flattening stopper so that an upper surface of the third interlayer insulation layer 410 and an upper surface of the capping layer 408 exist on the same line. The flattening process is performed using, for example, a CMP or an etch-back method. Subsequently, only the capping layer is selectively etched so that the capping layer 408 remains by a determined thickness, to form recesses on the line patterns.

In FIG. 18, the masking layer 412 is formed on an entire face of the semiconductor substrate containing the recess. The masking layer 412 is preferably formed of a polysilicon layer through a CVD process, a LPCVD process, a PECVD process, a SACVD process, a sputtering method, or an atomic layer deposition process. In forming the masking layer 412 as the polysilicon layer, the etch selection rate between the third interlayer insulation layer and the masking layer is very large (about 40:1), thus an etching hardly occurs in a subsequent step of forming a self-aligned contact. Thus, when performing an etching process using the masking layer as an etch mask, a storage node contact can be formed without a misalignment.

Contrary to the conventional art, the process of flattening the masking layer is omitted so that an upper surface of the third interlayer insulation layer and an upper surface of the masking layer exist on the same line. Embodiments of the invention use the masking layer as an etch mask, the masking layer being masked horizontally with the line pattern and being also masked vertically to the line pattern, thus flattening the masking layer to leave the masking layer only in a horizontal direction with the line pattern is unnecessary.

Furthermore, it is unnecessary to flatten the masking layer in order to perform a subsequent photolithography process after forming the masking layer. That is, the masking layer is first deposited in shallow recesses formed in an upper part of the line patterns, and then, is deposited on the third interlayer insulation layer, hence the upper part of the third interlayer insulation layer is flat enough not to require a specific flattening process.

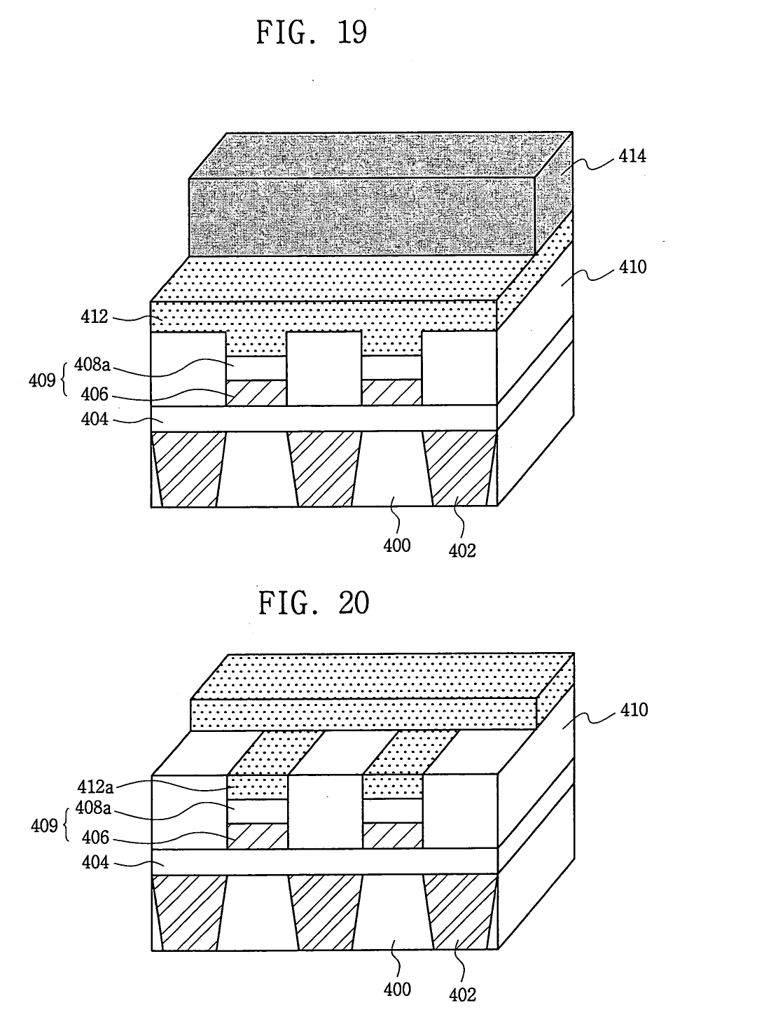

In FIG. 19, a photoresist pattern 414, which is vertical to the line pattern 409 and which masks a portion of the masking layer 412, is formed on the masking layer 412. The photoresist pattern 414 exposes a portion where a self-aligned contact will be formed and a portion of the line pattern, and masks a portion of the masking layer, and is also formed vertically to the line pattern 409. Furthermore, the photoresist pattern 414 is formed by depositing a photosensitive layer, e.g., photoresist, on the masking layer 412, then, by performing a photolithography process.

In FIG. 20, the masking layer 412 is etched to expose the third interlayer insulation layer 410 by using the photoresist pattern 414 as an etch mask. In etching the masking layer 412, the masking layer 412 existing on an upper part of the line pattern 409 may be partially etched to form a recess (not shown). Thus, in order to sufficiently function as an etch mask of the masking layer 412 in a subsequent process, etching equipment should be controlled appropriately. It is desirable to form the recess below an upper surface of the third interlayer insulation layer 410 within a range of 200 Å. Then, the photoresist pattern 414 remaining on the masking layer 412a is removed through an ashing process, resulting in the structure illustrated in FIG. 20.

As shown in FIG. 20, not only is the upper part of the line pattern masked with the masking layer, but the masking layer is also formed on the insulation layer, being stepped with the masked upper part of the line pattern vertically to the line pattern. In particular, if the masking layer is formed of polysilicon material, an etch selection rate between the third interlayer insulation layer made of an insulation layer of oxide series and the masking layer becomes very large, thus the masking layer is hardly etched in a subsequent process of forming a self-aligned contact. In other words, when using the masking layer as an etch mask, a sufficient alignment margin can be guaranteed by a self-alignment through the masking layer, even in cases where a design rule of the semiconductor device is fine, therefore a self-aligned contact may be formed without misalignment.

In the conventional art, the masking layer is formed only on the line pattern, and only a shallow photoresist pattern is formed in a vertical direction to the line pattern, to be used as an etch mask. Thus, it is difficult to prevent misalignment of a self-aligned contact formed vertically to a bit line. This is based upon the fact that when a thickness of photoresist becomes low to obtain a finer patterning, an over-etching is needed to prevent a contact hole from being opened. At this time, the lowered photoresist can not sufficiently function as a mask.

In the meantime, according to embodiments of the invention, since the masking layer for masking an upper part of the line pattern is formed to be used as an etch mask, a misalignment of bit line and self-aligned contact can be prevented. Furthermore, since the masking layer to be used at the etch mask is masked vertically even to the line pattern that is formed together with that the masking layer, an alignment margin can be sufficiently ensured even in a vertical direction to a bit line. Therefore, embodiments of the invention prevent a misalignment between the bit line and contacts formed vertically to the bit line.

In FIG. 21, the remaining masking layer 412a, which is formed by masking the upper part of line pattern and which is masked vertically to the line pattern, is used as the etch mask, to sequentially etch the third and second interlayer insulation layers 410, 404, and to form a contact hole between the stripe type line patterns 409.

Furthermore, the remaining masking layer 412a and the photoresist pattern 414 are used as the etch mask to sequentially etch the third and second interlayer insulation layers 410, 404 and to form a contact hole. Next, the photoresist pattern 414 can be removed through an ashing process.

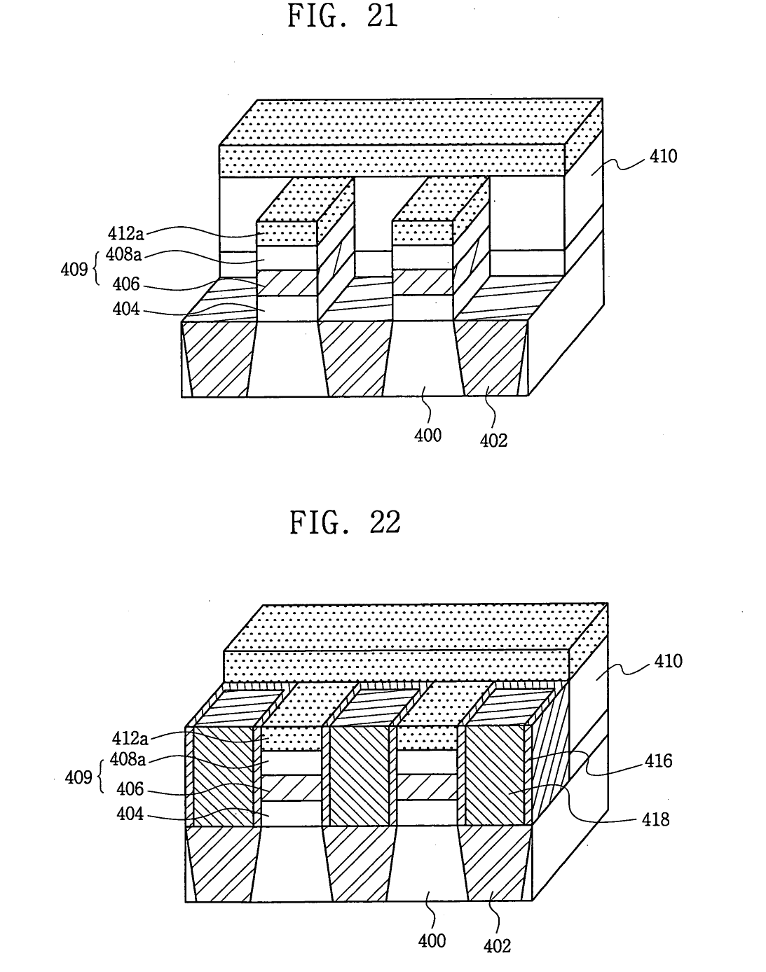

In FIG. 22, a spacer 416 is formed in a sidewall of the contact hole, and a contact plug 418 is formed by filling up the contact hole with conductive material. The spacer 416 can be formed of a silicon nitride layer to mask a sidewall of the contact hole. The spacer 416 is formed by depositing a silicon nitride layer in a sidewall of the contact hole and by performing an etch-back process. As an example, the conductive material may be a polysilicon material.

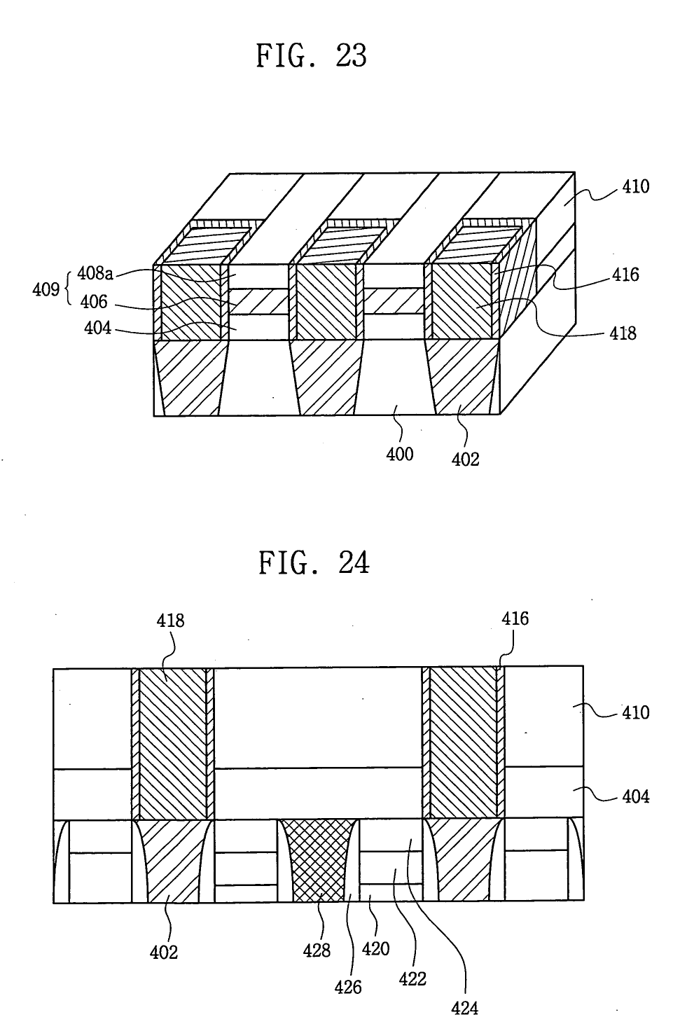

In FIG. 23, the capping layer 408a formed on the line pattern is used as a flattening stopper, and the remaining masking layer 412a is removed through a flattening process such as, for example, a CMP process. Hence, a storage node contact is formed through which a lower part of the contact plug 418 is electrically connected to an upper part of the contact pad 402.

FIG. 24 is a sectional view taken along line II-II′ of FIG. 14, illustrating a contact formed according to an exemplary embodiment of the invention.

Referring to FIG. 24, a gate oxide layer 420, a gate conductive layer 422, and a gate capping layer 424 are sequentially accumulated on a semiconductor substrate, and a storage contact pad 426 and a bit line contact pad 428 are formed on an active region. Then, the second interlayer insulation layer 404 and the third interlayer insulation layer 410 are accumulated, and in line with that, a storage pad contact 418 is formed piercing through the second interlayer insulation layer 404 and the third interlayer insulation layer 410. According to the exemplary embodiment of the invention, the storage node contact 418 is formed without a misalignment so as not to generate an electrical short between the storage node contacts, and this results in FIG. 24.

As described above, according to embodiments of the invention, a masking layer, which masks an upper part of bit line and which is masked vertically to a bit line, is utilized to prevent a misalignment in forming a contact.

Also, a masking layer, which is stepped with a masking layer for masking an upper part of bit line and which is masked vertically to a bit line, is utilized to prevent a misalignment in forming a contact.

In addition, there is an advantage that a misalignment between contacts formed vertically to a bit line is prevented so as not to generate a short between the contacts.

Embodiments of the invention may be practiced in many ways. What follows are exemplary, non-limiting descriptions of some of these embodiments.

An embodiment of the invention provides a method of forming a contact between line patterns on a semiconductor substrate on which the line patterns surrounded with an insulation layer and each composed of a bit line conductive layer and a capping layer are formed in line; the method includes forming a masking layer on the insulation layer and the line pattern, the masking layer being for masking a portion where the contact is not formed, among upper parts of the insulation layer and the line pattern, forming a contact hole between the linearly formed line patterns by etching the insulation layer through use of the masking layer as an etch mask, and forming a spacer in a sidewall of the contact hole and then filling up the contact hole with conductive material to form the contact.

Another embodiment of the invention provides a method of forming a contact, including sequentially accumulating a second insulation layer, a bit line conductive layer and a capping layer on a semiconductor substrate on which a contact pad surrounded with a first insulation layer is formed; linearly forming a plurality of line patterns by performing a photolithography and etching process on the capping layer and the bit line conductive layer, then, forming a third insulation layer on an entire face of the semiconductor substrate involving the line patterns; flattening the third insulation layer so that an upper surface of the third insulation layer and an upper surface of the capping layer exist on the same line, then, selectively etching the capping layer so that the capping layer remains by a determined thickness to form a recess on the line patterns; forming a masking layer on an entire face of the semiconductor substrate containing the recess, next, forming a photoresist pattern on the third insulation layer, the photoresist pattern being vertical to the line pattern and being for masking a portion of the masking layer; etching the masking layer by using the photoresist pattern as an etch mask so that the third insulation layer is exposed, then, removing the photoresist pattern; sequentially etching the third and second insulation layers by using the remaining masking layer as an etch mask, to form a contact hole between the linearly formed line patterns; and forming a spacer in a sidewall of the contact hole, next, filling up the contact hole with conductive material to form a contact.

Another embodiment of the invention provides a method of forming a contact between line patterns on a semiconductor substrate on which the line patterns surrounded with an insulation layer and each composed of a bit line conductive layer and a capping layer are formed in line, the method including forming a masking layer on the insulation layer and the line pattern, the masking layer being for masking an upper part of the line pattern and being for masking a portion of the insulation layer in a vertical direction to the line pattern to be stepped with the masked portion of the line pattern; forming a contact hole between the linearly formed line patterns by etching the insulation layer through use of the masking layer as an etch mask; and forming a spacer in a sidewall of the contact hole, then, filling up the contact hole with conductive material to form a contact.

It will be apparent to those skilled in the art that modifications and variations can be made to the exemplary embodiments without deviating from the spirit or scope of the invention. Thus, it is intended that the invention cover any such modifications and variations of this invention provided they come within the scope of the appended claims and their equivalents. Accordingly, these and other changes and modifications are seen to be within the true spirit and scope of the invention as defined by the appended claims.

I claim:

1. A method of forming a contact comprising:
forming an insulation layer on a semiconductor substrate;
forming line patterns that are surrounded by the insulation layer, each line pattern composed of a bit line conductive layer and a capping layer;
forming a masking layer on the insulation layer and the line patterns, the masking layer masking a portion of the insulation layer and the line patterns where the contact is not formed;
forming a contact hole between the line patterns by etching the insulation layer using the masking layer as an etch mask; and
forming a spacer in a sidewall of the contact hole; and
filling the contact hole with a conductive material to form the contact.

2. The method of claim 1, wherein forming the masking layer comprises:
flattening the insulation layer so that an upper surface of the insulation layer and an upper surface of the capping layer exist on the same line;
selectively etching the capping layer so that the capping layer remains by a determined thickness to form a recess on the line patterns;
forming the masking layer on a face of the semiconductor substrate containing the recess;
forming a photoresist pattern on the insulation layer, said photoresist pattern being vertical to the line pattern and being for masking a portion of the masking layer;
etching the masking layer by using the photoresist pattern as an etch mask so that the insulation layer is exposed; and
removing the photoresist pattern.

3. The method of claim 2, wherein forming the masking layer comprises:
forming the masking layer to mask an upper part of the line pattern and to be stepped with the masked portion of the line pattern; and
forming the masking layer to mask a portion of the insulation layer vertical to the line pattern.

4. The method of claim 3, wherein forming the masking layer further comprises forming the masking layer through any one selected from among a CVD (Chemical Vapor Deposition) process, an LPCVD (Low Pressure Chemical Vapor Deposition) process, a PECVD (Plasma Enhanced Chemical Vapor Deposition) process, an SACVD (Semi-Atmospheric Chemical Vapor Deposition) process, a sputtering method, and an atomic layer deposition process.

5. The method of claim 3, wherein forming the masking layer further comprises forming the masking layer with a material having an etch selection rate of at least 40:1 with respect to the insulation layer.

6. The method of claim 3, wherein forming the masking layer further comprises forming the masking layer of a polysilicon material.

7. The method of claim 2, wherein forming the insulation layer comprises forming the insulation layer of one selected from the group consisting of a USG (Undoped Silicate Glass) layer, a BPSG (Boron Phosphorus Silicate Glass) layer, a PSG (Phosphor Silicate Glass) layer, a PE-TEOS (Plasma Enhanced Tetra Ethyl Otho Silicate) layer, and a multilayer containing at least two selected from the USG, BPSG, PSG, and PE-TEOS layers.

8. The method of claim 2, wherein forming line patterns comprises forming the bit line conductive layer of a layer chosen from the group consisting of a single layer made of polysilicon, a single layer made of silicide, and a multilayer containing both a polysilicon layer and a silicide layer.

9. The method of claim 2, wherein forming the line patterns comprises forming the capping layer with a silicon nitride layer that has an etch selection rate with respect to the insulation layer and that has a refractive index of about 2.2 through 2.5.

10. The method of claim 1, wherein forming the spacer comprises forming the spacer with a silicon nitride material.

11. The method of claim 1, wherein filling the contact hole with the conductive material comprises filling the contact hole with a polysilicon layer.

12. The method of claim 1, wherein filling the contact hole with the conductive material to form the contact comprises electrically connecting a lower part of the contact to an upper part of a contact pad.

13. The method of claim 1, further comprising flattening and removing the remaining masking layer after forming the contact.

14. The method of claim 13, wherein flattening the remaining masking layer comprises performing a process chosen from the group consisting of a CMP (Chemical Mechanical Polishing) process and an etch-back process.

15. A method of forming a contact comprising:
sequentially accumulating a second insulation layer, a bit line conductive layer and a capping layer on a semiconductor substrate on which a contact pad surrounded with a first insulation layer is formed;
linearly forming a plurality of line patterns by performing a photolithography and etching process on the capping layer and the bit line conductive layer;
forming a third insulation layer on a face of the semiconductor substrate including the line patterns;
flattening the third insulation layer so that an upper surface of the third insulation layer and an upper surface of the capping layer exist on the same line;
selectively etching the capping layer so that the capping layer remains by a determined thickness to form a recess on the line patterns;
forming a masking layer on a face of the semiconductor substrate containing the recess;
forming a photoresist pattern on the masking layer, the photoresist pattern being vertical to the line pattern and masking a portion of the masking layer;
etching the masking layer by using the photoresist pattern as an etch mask so that the third insulation layer is exposed;
removing the photoresist pattern;
sequentially etching the third and second insulation layers by using the remaining masking layer as an etch mask to form a contact hole between the linearly formed line patterns;
forming a spacer in a sidewall of the contact hole; and
filling the contact hole with a conductive material to form a contact.

16. The method of claim 15, wherein filling the contact hole with a conductive material to form a contact comprises electrically connecting a lower part of the contact to an upper part of the contact pad.

17. The method of claim 15, further comprising forming a barrier layer made of one selected from the group consisting of a Ti layer, a TiN layer, and a Ti/TiN multilayer before forming the bit line conductive layer.

18. The method of claim 15, further comprising flattening and removing the remaining masking layer.

19. A method of forming a contact between line patterns on a semiconductor substrate on which the line patterns surrounded with an insulation layer and each composed of a bit line conductive layer and a capping layer are formed in line, the method comprising:
forming a masking layer on the insulation layer and the line patterns, the masking layer being for masking an upper part of the line patterns and being for masking a portion of the insulation layer in a vertical direction to the line patterns to be stepped with the masked portion of the line patterns;
forming a contact hole between the line patterns by etching the insulation layer through use of the masking layer as an etch mask; and
forming a spacer in a sidewall of the contact hole, and then filling the contact hole with conductive material to form the contact.

20. A method of forming a hard mask to form a storage node contact, on a semiconductor substrate on which line patterns surrounded with an insulation layer and each composed of a bit line conductive layer and a capping layer are formed in line, said method comprising:
forming a masking layer on a face of the semiconductor substrate;
forming a photoresist pattern on the masking layer through a photolithography process, the photoresist pattern being vertical to the line pattern and being for masking a portion of the masking layer; and
etching the masking layer to expose the insulation layer by using the photoresist pattern as an etch mask so that the masking layer is formed on the insulation layer and the line pattern, the masking layer being for masking a portion where the storage node contact is not formed, among upper parts of the insulation layer and the line patterns.
